(19) United States
(12) Patent Application Publication
(10) Pub. No.: US 2025/0188610 A1
(43) Pub. Date: Jun. 12, 2025

(54) Device for Performing Plasma Treatment, and Method for Performing Plasma Treatment

(71) Applicant: Tokyo Electron Limited, Tokyo (JP)

(72) Inventor: Jianming HAO, Yamanashi (JP)

(21) Appl. No.: 19/049,777

(22) Filed: Feb. 10, 2025

Related U.S. Application Data
(63) Continuation of application No. PCT/JP2023/029139, filed on Aug. 9, 2023.

(30) Foreign Application Priority Data
Aug. 23, 2022 (JP) 2022-132731

(51) Int. Cl. C23C 16/455; C23C 16/507; H01J 37/32

(52) U.S. Cl. CPC C23C 16/45536; C23C 16/45519; C23C 16/45544; C23C 16/45565; C23C 16/507; H01J 37/32091; H01J 37/3244; H01J 37/32495; H01J 2237/0213; H01J 2237/3321

(57) ABSTRACT

An apparatus for performing plasma processing by supplying a plasma-state processing gas to a substrate in a processing chamber comprises a placing table disposed in the processing chamber and on which the substrate is placed, a plasma generation space disposed above the placing table and constituting a plasma generation mechanism configured to convert the processing gas into plasma, a processing gas supply part configured to supply the processing gas to the plasma generation space, a shower plate disposed between the plasma generation space and a substrate processing space where the placing table is disposed, and having a plurality of processing gas supply holes through which the plasma-state processing gas flows from the plasma generation space toward the processing space. The apparatus comprises a cover gas supply mechanism configured to supply a cover gas that flows to cover sidewall surfaces of the plurality of processing gas supply holes.

### CROSS-REFERENCE TO RELATED APPLICATIONS

This application is a bypass continuation application of International Application No. PCT/JP2023/029139 having an international filing date of Aug. 9, 2023 and designating the United States, the International Application being based upon and claiming the benefit of priority from Japanese Patent Application No. 2022-132731 filed on Aug. 23, 2022, the entire contents of which are incorporated herein by reference.

### TECHNICAL FIELD

The present disclosure relates to a plasma processing apparatus and a plasma processing method.

### BACKGROUND

A chemical vapor deposition (CVD) method and an atomic layer deposition (ALD) method are known as treatment for performing film formation on a semiconductor wafer (hereinafter, referred to as “wafer”) in a semiconductor device manufacturing process. In the film formation, a raw material gas containing a film raw material reacts with a reactive gas that is a processing gas that oxidizes or reduces the raw material gas to deposit a substance that becomes a film on the wafer.

In film formation, highly reactive active species obtained by converting a reactive gas into plasma may be used. For example, Japanese Laid-open Patent Publication No. 2019-203155 discloses a technique in which high-frequency electric field is generated in a gas diffusion space between an upper electrode and a shower plate to produce capacitively coupled plasma, thereby dissociating a reactive gas. The dissociated reactive gas is supplied to a substrate on a stage through a plurality of gas injection holes formed in the shower plate, so that film formation is performed.

The treatment using active species in a plasma-state gas is also performed in etching or modification other than the film formation.

### SUMMARY

The present disclosure provides a technique for performing plasma processing by supplying a processing gas to a substrate while suppressing deactivation of radicals in the plasma-state processing gas.

The present disclosure provides an apparatus for performing plasma processing by supplying a plasma-state processing gas to a substrate in a processing chamber, comprising:
a placing table disposed in the processing chamber and on which the substrate is placed;
a plasma generation space disposed above the placing table and constituting a plasma generation mechanism configured to convert the processing gas into plasma;
a processing gas supply part configured to supply the processing gas to the plasma generation space;
a shower plate disposed between the plasma generation space and a substrate processing space where the placing table is disposed, and having a plurality of processing gas supply holes through which the plasma-state processing gas flows from the plasma generation space toward the processing space, and a cover gas supply mechanism configured to supply a cover gas that flows to cover sidewall surfaces of the plurality of processing gas supply holes.

### BRIEF DESCRIPTION OF THE DRAWINGS

FIG. 1 is a longitudinal side view of a film forming apparatus according to the present disclosure.

FIG. 2 is an enlarged longitudinal side view of a plasma generation space of the film forming apparatus.

FIG. 3 is an enlarged longitudinal side view of a shower plate.

FIG. 4 is a perspective view of a shower plate according to a first embodiment, which is seen from the top.

FIG. 5 is a perspective view of the shower plate according to the first embodiment, which is seen from the bottom.

FIG. 6 is an enlarged longitudinal side view of a shower plate according to the first embodiment.

FIG. 7 is a perspective view of a shower plate according to a second embodiment, which is seen from the top.

FIG. 8 is a perspective view of the shower plate according to the second embodiment, which is seen from the bottom.

FIG. 9 is an enlarged longitudinal perspective view of the shower plate according to the second embodiment.

FIG. 10 is an enlarged longitudinal side view of a shower plate according to a third embodiment.

FIG. 11 is a longitudinal side view of a film forming apparatus including a plurality of shower plates.

FIG. 12 shows simulation results illustrating the distribution of the mass fraction of radicals in a processing gas flowing through a reactive gas supply hole.

### DETAILED DESCRIPTION

### <Film Forming Apparatus>

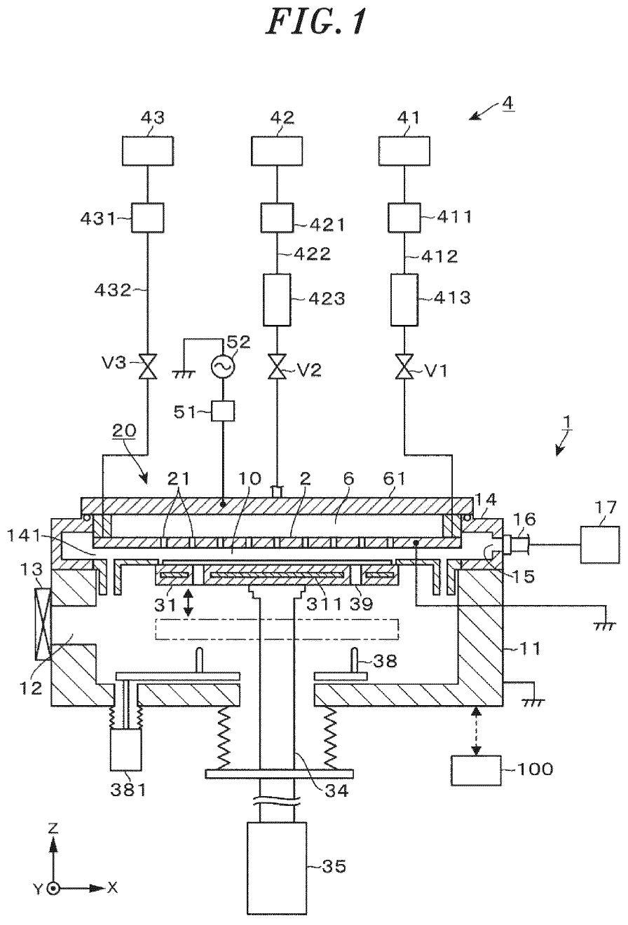

First, an example of an overall configuration of a film forming apparatus 1, which is an embodiment of “apparatus for performing plasma processing” according to the present disclosure, will be described with reference to FIG. 1. The film forming apparatus 1 of this example is configured to supply a plasma-state reactive gas (processing gas) and a raw material gas containing a film raw material to the wafer W, and form a film of a desired material on the surface of the wafer W. The film formed on the wafer W is not particularly limited, and may be a metal oxide film or a metal nitride film for forming an insulating film, or may be a metal film. As will be described later, the film forming apparatus 1 has a configuration in which deactivation of radicals that are active species can be suppressed when the plasma-state reactive gas is supplied to the wafer W in a plasma generation space 6.

The film forming apparatus 1 is configured to supply a raw material gas containing a film raw material such as a metal compound and a plasma-state reactive gas into a processing chamber 11 that accommodates and processes the wafer W, and form a film of a desired material on the surface of the wafer W. The film forming method may be a CVD method in which a raw material gas and a plasma-state reactive gas are continuously supplied to deposit a film material on the surface of the wafer W. Alternatively, the film forming method may be an ALD method in which a thin film of a film material is laminated by alternatively performing the supply and exhaust of the raw material gas and the supply and exhaust of the plasma-state reactive gas and repeating the adsorption of the raw material gas on the wafer W and the reaction of the reactive gas.

The processing chamber 11 in this example is made of a flat cylindrical metal, and is grounded. A loading/unloading port 12 for loading/unloading the wafer W, and a gate valve 13 for opening/closing the loading/unloading port 12 are formed on the sidewall of the processing chamber 11. An exhaust duct 14 having a circular shape in plan view is disposed above the loading/unloading port 12. A slit-shaped exhaust port 141 extending in the circumferential direction is formed on the inner peripheral surface of the exhaust duct 14. An opening 15 is formed on the sidewall surface of the exhaust duct 14, and one end of an exhaust line 16 is connected through the opening 15. The other end of the exhaust line 16 is connected to an exhaust mechanism 17 including a pressure control mechanism or a vacuum pump.

A placing table 31 for placing the wafer W horizontally is provide in the processing chamber 11. A heater 311 for heating the wafer W is provided in the placing table 31. The upper end of a rod-shaped support member 34 that extends in the vertical direction while penetrating through the bottom portion of the processing chamber 11 is connected to the central portion of the bottom surface of the placing table 31. A lifting mechanism 35 is connected to the lower end of the support member 34. The lifting mechanism 35 allows the placing table 31 to move vertically between a lower position indicated by a dashed-dotted line in FIG. 1 and an upper position indicated by a solid line in FIG. 1. The lower position is a transfer position for transferring the wafer W to and from a transfer mechanism (not shown) for the wafer W that enters the processing chamber 11 from the loading/unloading port 12. The upper position is a processing position where film formation is performed on the wafer W. At the processing position, the space above the placing table 31 constitutes the processing space 10 for processing the wafer W.

Further, a plurality of support pins 38, which can be raised and lowered by a lifting mechanism 381, are arranged below the placing table 31. When the placing table 31 is located at the transfer position, the support pins 38 are raised and lowered to protrude and retract from the upper surface of the placing table 31 through through-holes 39 formed in the placing table 31. Due to such an operation, the wafer W can be transferred between the placing table 31 and the transfer mechanism.

### <Gas Supply System 4>

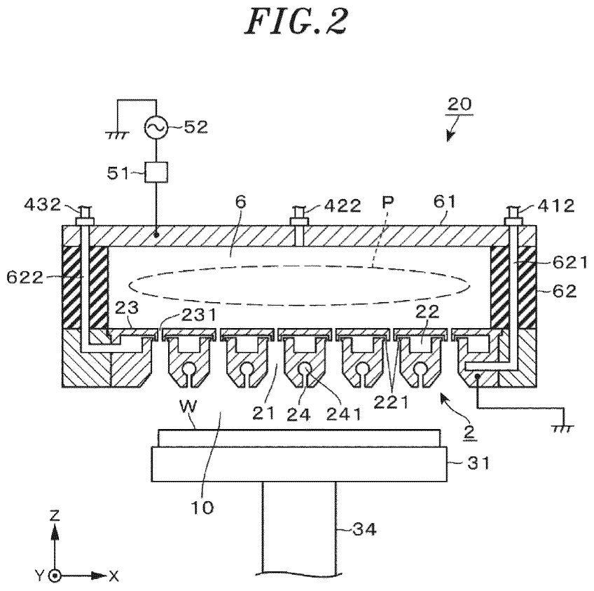

A gas shower head 20 is provided in the circular exhaust duct 14, i.e., above the placing table 31, to supply a plasma-state reactive gas toward the processing space 10. The specific configuration of the gas shower head 20 will be described in FIG. 2 and subsequent drawings, so that an example of the configuration of the gas supply system 4 that supplies various gases toward the gas shower head 20 will be described first.

The gas supply system 4 in this example includes a raw material gas supply source 41 that supplies a raw material gas containing a precursor (film raw material) that is a raw material of the film material of the film to be formed on the wafer W, a reactive gas supply source 42 that supplies a reactive gas that reacts with the precursor to obtain the film material, and a cover gas supply source 43 that supplies a cover gas to suppress deactivation of the plasma-state reactive gas.

In the case of forming a film containing a metal, such as titanium, as the film material, a raw material gas containing TiCl₄ can be used, for example. The reactive gas may be oxygen gas or ozone gas used in the case of forming an oxide film, ammonia gas in the case of forming a nitride film, and hydrogen gas, which is a reducing gas used in the case of forming a metal film by reducing a precursor. An auxiliary gas such as argon gas may be added to the reactive gas to assist the conversion of the reactive gas into plasma. The cover gas may be helium gas, argon gas, or an inert gas such as nitrogen gas.

One end of a raw material gas supply line 412 is connected to the raw material gas supply source 41, and a flow rate controller 411 and a valve V1 are sequentially provided in the raw material gas supply line 412 from the upstream side. Further, one end of a reactive gas supply line 422 is connected to the reactive gas supply source 42, and a flow rate controller 421 and a valve V2 are sequentially provided in the reactive gas supply line 422 from the upstream side. In addition, in the case of forming a film by ALD, for example, storage tanks 413 and 423 for respective gases may be provided on the upstream of side of the valves V1 and V2 in order to supply a sufficient amount of raw material gas and reactive gas in a short period of time.

Further, one end of a cover gas supply line 432 is connected to the cover gas supply source 43, and a flow rate controller 431 and a valve V3 are sequentially provided in the cover gas supply line 432 from the upstream side.

Further, the configuration of the gas supply system 4 is not limited to this example. For example, a purge gas supply line for supplying a purge gas that promotes the discharge of the raw material gas and the reactive gas from the processing chamber 11 may be joined to the gas supply lines 412, 422, and 432. The purge gas may be, e.g., an inert gas such as argon gas or nitrogen gas.

The other ends of the gas supply lines 412, 422, and 432 are connected to the gas shower head 20. The specific connection position where they are connected to the gas shower head 20 will be described in FIG. 2 and subsequent drawings.

Further, the gas shower head 20 is connected to a radio frequency (RF) power supply 52 that applies an RF power for plasma generation via a matching device 51. The RF power supply 52 and the gas shower head 20 are connected to a ground terminal. The connection positions where the RF power supply 52 and the ground terminal are connected to the gas shower head 20 will be described in FIG. 2 and subsequent drawings.

### <Gas Shower Head 20>

Next, an example of a configuration of a gas shower head 20 for converting a reactive gas into plasma and supplying it toward the processing space 10 will be described with reference to FIG. 2. The gas shower head 20 of this example is configured such that an electrode plate 61 and a shower plate 2 are horizontally arranged to face each other with a circular sidewall portion 62 made of a dielectric material interposed therebetween. The electrode plate 61 and the shower plate 2 are formed in a circular plate shape and made of a metal, for example. A parallel plate type plasma generation mechanism is formed by connecting the RF power supply 52 to the electrode plate 61 and connecting the shower plate 2 to the ground terminal.

In the above-described plasma generation mechanism, the space between the electrode plate 61 and the shower plate 2 spaced apart from each other constitutes the plasma generation space 6 for converting the reactive gas into plasma. In the film forming apparatus 1 in this example, the plasma-state reactive gas in the plasma generation space 6 is supplied to the processing space 10 (the wafer W on the placing table 31) through the shower plate 2 disposed between the plasma generation space 6 and the processing space 10. From the above, the film forming apparatus 1 of the present embodiment constitutes a remote-type plasma processing apparatus.

The reactive gas is supplied from the reactive gas supply line 422 to the plasma generation space 6 through the electrode plate 61, as shown in FIG. 2, for example. From the above, the reactive gas supply line 422 and the reactive gas supply source 42 connected to the upstream side thereof, the flow rate controller 421, and the like constitute the processing gas supply part of the present embodiment.

Here, as shown in FIGS. 1 and 2, a plurality of reactive gas supply holes (processing gas supply holes) 21 are formed in the shower plate 2. The plasma-state reactive gas in the plasma generation space 6 flows through the reactive gas supply holes 21 and is supplied to the processing space 10. On the other hand, when the active species of the plasma-state reactive gas are brought into contact with the sidewall surfaces of the reactive gas supply holes 21 made of a grounded metal, the radicals that are active species contributing to the reaction with the precursor may be deactivated.

Therefore, in the present embodiment, the shower plate 2 is configured to reduce the concentration of radicals that are brought into contact with the sidewall surfaces of the reactive gas supply holes 21 by supplying a cover gas, e.g., an inert gas to cover the sidewall surface, thereby suppressing the deactivation of the radicals. The configuration and specific embodiments of the shower plate 2 will be described below with reference to FISG. 3 to 9. Further, since FIG. 1 is a diagram for explaining the overall configuration of the film forming apparatus 1, the configuration of the shower plate 2 is illustrated in a simplified manner.

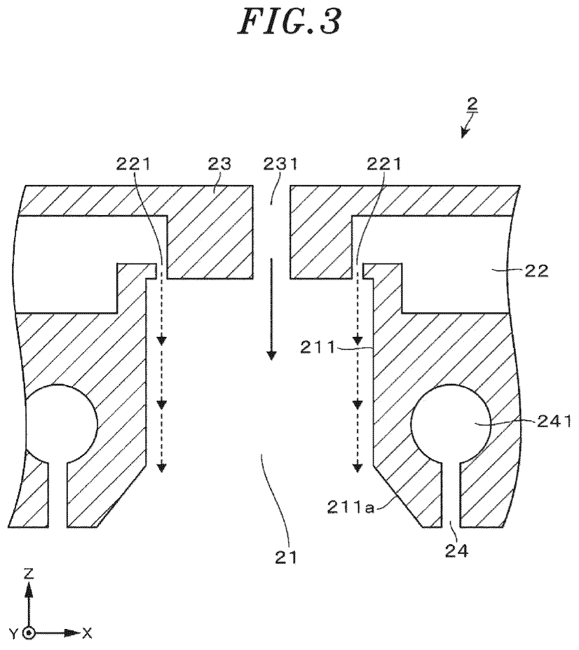

As shown in FIGS. 2 and 3, the shower plate 2 has a plurality of reactive gas supply holes 21 that penetrate through the shower plate 2 in the vertical direction and serve as channels through which the plasma-state reactive gas flows from the plasma generation space 6 toward the processing space 10.

The upper surface side of each reactive gas supply hole 21, i.e., the opening on the plasma generation space 6 side, is covered by a trap plate 23 that is a metal plate-shaped member. The trap plate 23 has one or multiple gas inlet holes 231 whose total opening area is smaller than the opening area of the reactive gas supply holes 21. The opening diameter of the gas inlet hole 231 may be, e.g., 0.4 mm within a range of 0.1 mm to 1.0 mm.

By allowing the reactive gas to flow from the plasma generation space 6 into the reactive gas supply holes 21 through the gas inlet holes 231 with a small opening area, the reactive gas can be supplied to the processing space 10 in a state where some of ions in the plasma P are removed. Since ions have high energy, they may cause roughness of the film formed on the wafer W or damage to the base. Therefore, it is preferable to supply the plasma-state reactive gas to the wafer W with a reduced content of ions.

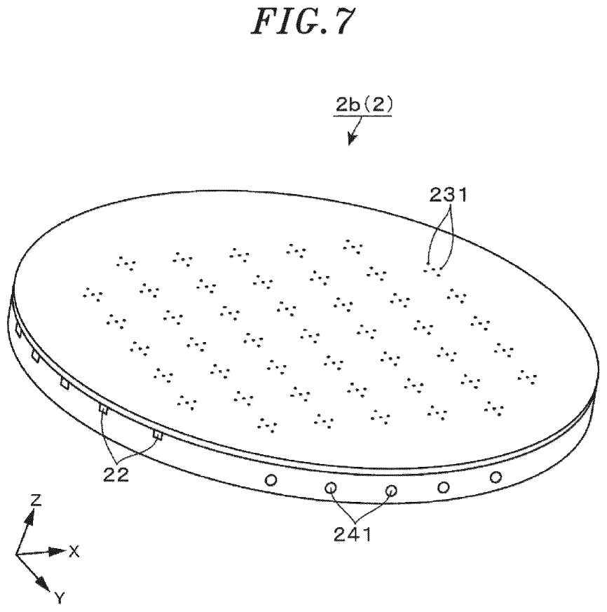

FIGS. 3, 4 to 6 show examples in which one gas inlet hole 231 is provided for each reactive gas supply hole 21, and FIGS. 7 to 9 and 10 show examples in which multiple gas inlet holes 231 are provided for each reactive gas supply hole 21.

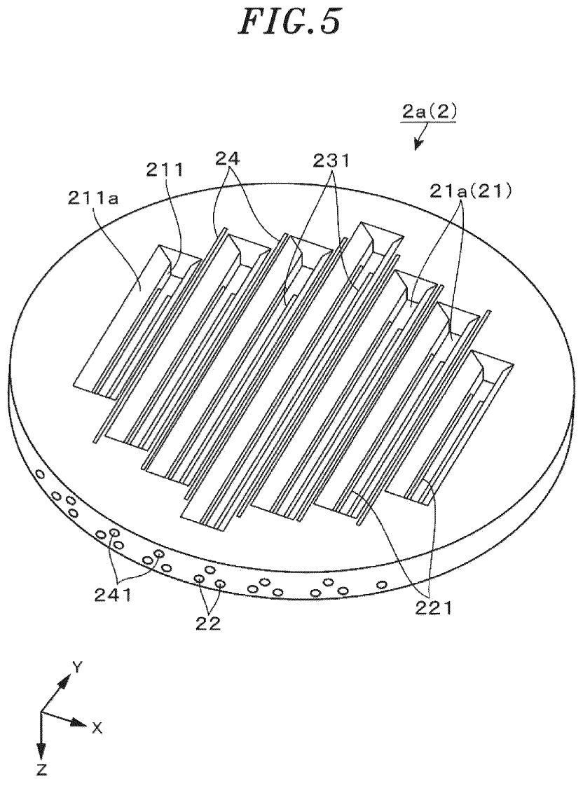

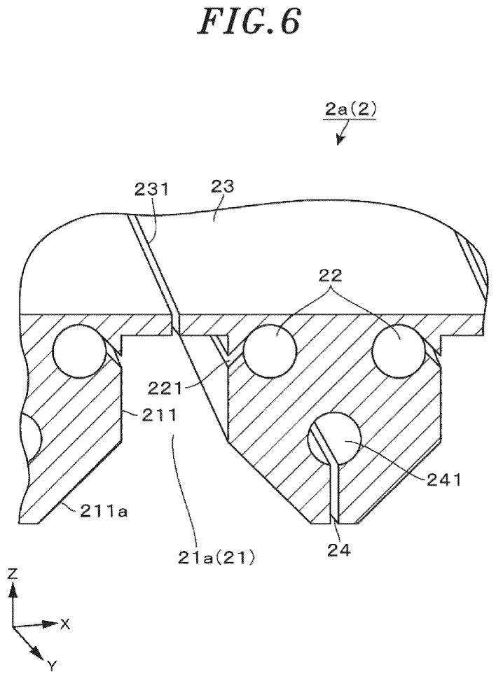

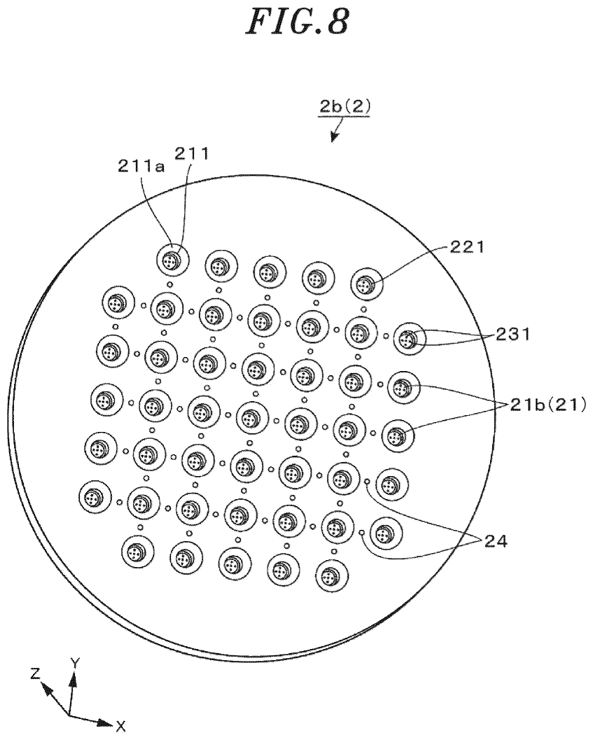

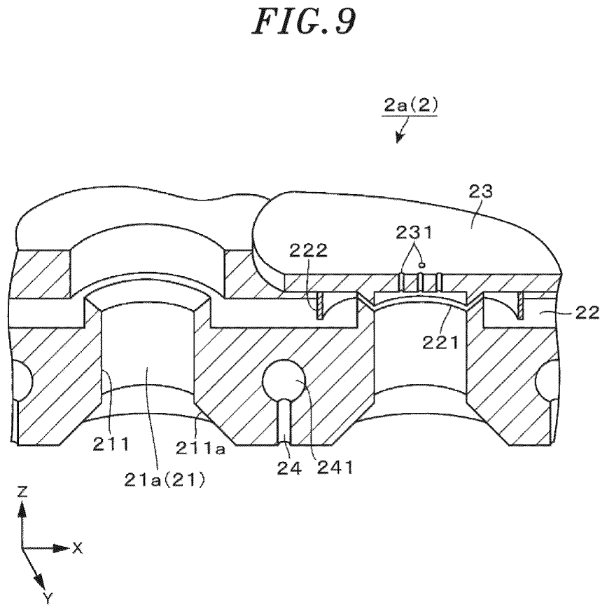

The planar shape of the reactive gas supply hole 21 is not particularly limited. However, as will be shown in the first embodiment to be described later, each reactive gas supply hole 21a may be configured as an elongated opening (see FIGS. 5 and 6), or as will be shown in the second embodiment, each reactive gas supply hole 21b may be configured as a small hole shape (see FIGS. 8 and 9). When the reactive gas supply hole 21a is configured as an elongated opening, the opening dimension in the short side direction viewed from the placing table 31 side can be, e.g., 10 mm within a range of 10 mm to 15 mm. Further, when the reactive gas supply hole 21b is a circular small hole, the opening diameter viewed from the placing table 31 side can be, e.g., 10 mm within a range of 10 mm to 15 mm.

All the reactive gas supply holes 21 are common in that the sidewall surfaces 211 of the reactive gas supply holes 21 are disposed near the flow of plasma-state reactive gas (indicated by the solid arrow in FIG. 3) passing through the gas inlet holes 231 and directed toward the processing space 10 (see FIG. 3).

In the example shown in FIG. 3, a sidewall surface 211 on the lower end side of each reactive gas supply hole 21 includes an area defined by a tapered surface 211a in which the opening area of the reactive gas supply holes 21 gradually increases from the upstream side toward the downstream side of the flow of reactive gas. By gradually increasing the opening area of the reactive gas supply holes 21, the plasma-state reactive gas can be supplied to an area wider than the wafer W on the placing table 31.

Further, a cover gas supply hole 221 for supplying a cover gas is formed at the upstream end of the flow of the reactive gas in each reactive gas supply hole 21. The cover gas supplied from the cover gas supply hole 221 flows to cover the sidewall surface 211. The cover gas supply hole 221 is formed by a slit formed at a position where the cover gas is supplied along the inner circumferential surface of the sidewall surface 211 constituting the reactive gas supply hole 21, or is formed by arranging a plurality of small holes side by side.

As shown in FIGS. 2 and 3, a cover gas channel 22 through which the cover gas flows is formed in the shower plate 2. The cover gas channel 22 communicates with the cover gas supply hole 221 that supplies the cover gas to the sidewall surface 211 of the reactive gas supply hole 21. On the other hand, the base end side of the cover gas channel 22 is connected to the cover gas supply line 432 described above via a cover gas channel 622 formed in the sidewall portion 62 constituting the gas shower head 20, for example. A cover gas is supplied to the cover gas channel 22 from the cover gas supply source 43 via the cover gas supply line 432. The cover gas supply line 432 and the cover gas supply source 43 connected to the upstream side thereof, the flow rate controller 431, and the like correspond to the cover gas supply part of this example. The cover gas channel 22, the cover gas supply hole 221, and the above-described cover gas supply part constitute the cover gas supply mechanism of this example.

In addition to the above-described components, a plurality of raw material gas supply holes 24 are formed in the bottom surface of the shower plate 2 to supply a raw material gas toward the processing space 10 (the wafer W on the placing table 31). The raw material gas supply holes 24 are formed separately from the reactive gas supply holes 21 for supplying the plasma-state reactive gas. Each raw material gas supply hole 24 is connected to a raw material gas channel 241 formed in the shower plate 2, for example. The raw material gas channel 241 is formed separately from the cover gas channel 22 that supplies the cover gas, and the base end side of the raw material gas channel 241 is connected to the above-described raw material gas supply line 412 via the raw material gas channel 621 formed in the sidewall portion 62. The raw material gas is supplied from the raw material gas supply source 41 to the raw material gas channel 241 via the raw material gas supply line 412.

Further, it is not necessary to supply the cover gas to all the supply holes (the reactive gas supply holes 21 and the raw material gas supply holes 24) provided in the gas shower head 20. In this example, the raw material gas is directly supplied to the processing space 10 without being converted into plasma. As described above, the cover gas mechanism is supplied to suppress the deactivation of radicals in the plasma-state gas. From the above, the cover gas supply mechanism of this example does not necessarily supply the cover gas to the sidewall surfaces of the raw material gas supply holes 24 through which the raw material gas that has not converted into plasma flows.

A specific configuration example of the shower plate 2 described above will be described with reference to two embodiments.

### Shower Plate 2a According to First Embodiment

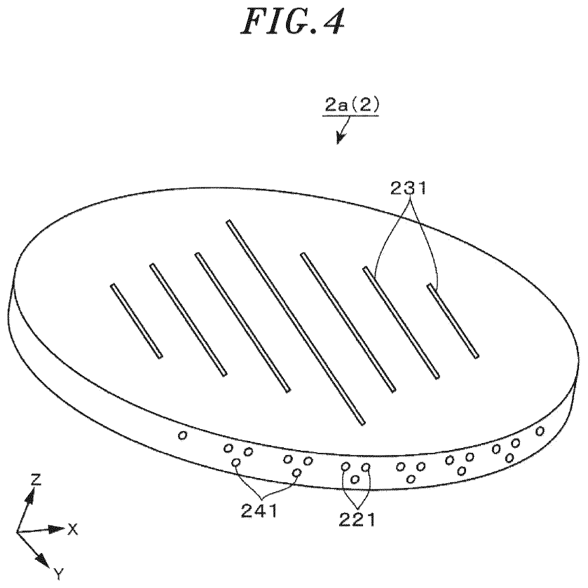

In the shower plate 2a according to the first embodiment shown in FIGS. 4 to 6, each reactive gas supply hole 21a is configured as an elongated opening. As shown in FIG. 4, which is a perspective view of the shower plate 2a seen from the plasma generation space 6 side, and FIG. 6, which is an enlarged longitudinal perspective view, the plurality of slit-shaped gas inlet holes 231 are arranged side by side on the upper surface side of the shower plate 2a to correspond to the positions where the reactive gas supply holes 21a are formed.

On the other hand, as shown in FIGS. 5 and 6, which are perspective views of the shower plate 2a seen from the placing table 31 side, the plurality of reactive gas supply holes 21a are arranged side by side on the bottom surface side of the shower plate 2a in a direction intersecting with the long side of the elongated opening. The slit-shaped cover gas supply hole 221 is formed at the upstream end side of the sidewall surface 211 along the long side direction of each reactive gas supply hole 21a. Further, on the bottom surface side of the shower plate 2a, a slit-shaped raw material gas supply hole 24 is formed between two adjacent reactive gas supply holes 21a.

### Shower Plate 2b According to the Second Embodiment

In the shower plate 2b according to the second embodiment shown in FIGS. 7 to 9, each reactive gas supply hole 21b is configured as a small circular hole. As shown in FIG. 7, which is a perspective view of the shower plate 2b seen from the plasma generation space 6 side, and FIG. 9, which is an enlarged vertical perspective view, the gas inlet holes 231 having a diameter smaller than that of the reactive gas supply hole 21b are formed on the upper surface side of the shower plate 2b. The plurality of gas inlet holes 231 are formed for each reactive gas supply hole 21b.

On the other hand, as illustrated in FIGS. 8 and 9 showing the shower plate 2b seen from the placing table 31 side, the reactive gas supply holes 21b, each being formed of multiple small holes, are formed on the bottom surface side of the shower plate 2b to open in a matrix pattern. At the upstream end of the sidewall surface 211 of each reactive gas supply hole 21b, a slit-shaped cover gas supply hole 221 is formed along the entire inner circumferential surface. Further, as shown in FIG. 9, in the cover gas channel 22 formed in the shower plate 2b, a baffle plate 222 for adjusting the flow rate of the cover gas flowing into the cover gas supply hole 221 is disposed at a position surrounding the slit-shaped cover gas supply hole 221. Further, the small hole-shaped raw material gas supply holes 24 are formed on the bottom surface side of the shower plate 2a to be positioned between the reactive gas supply holes 21b arranged in a matrix shape.

### <Controller 100>

Referring back to the description of FIG. 1, the film forming apparatus 1 includes a controller 100. The controller 100 includes a storage part that stores a program, a memory, and a computer having a CPU. The program includes commands (steps) for outputting control signals from the controller 100 to individual components of the film forming apparatus 1 and for loading/unloading the wafer W and performing film formation. The program is stored in the storage part of the computer, such as a flexible disk, a compact disk, a hard disk, a magneto-optical disk (MO), a non-volatile memory, or the like, and is read from the storage part and installed in the controller 100.

### <Film Formation>

Next, the operation of performing film formation on a wafer W as plasma processing using the film forming apparatus 1 having the above-described configuration will be described.

When the wafer W to be processed is transferred to an external vacuum transfer chamber, the gate valve 13 is opened, and a transfer mechanism (not shown) holding the wafer W enters the processing chamber 11 through the loading/unloading port 12. Then, the wafer W is transferred to the placing table 31 that stands by at the lower position using the support pins 38.

Then, the transfer mechanism is unloaded from the processing chamber 11, and the gate valve 13 is closed. At the same time, the pressure in the processing chamber 11 and the temperature of the wafer W are adjusted. Next, the reactive gas is supplied to the plasma generation space 6, and the high-frequency power is applied from the high-frequency power supply 52 to the electrode plate 61. As a result, the reactive gas supplied to the plasma generation space 6 is converted into plasma by capacitive coupling between the electrode plate 61 and the shower plate 2. As described above, an auxiliary gas such as argon gas may be supplied simultaneously as the plasma-state reactive gas.

When the plasma-state reactive gas is brought into contact with the upper surface of the trap plate 23 or passes through the gas inlet holes 231 formed in the trap plate 23, some of the ions are trapped and removed by the sheath potential of the sidewall surfaces of the gas inlet holes 231. On the upper surface of the trap plate 23 and the sidewall surfaces of the gas inlet holes 231, some of the radicals are also deactivated and trapped, but most of them pass through the gas inlet holes 231 and flow into the reactive gas supply holes 21.

As shown in FIG. 3, the plasma-state reactive gas that has passed through the gas inlet holes 231 and introduced into the reactive gas supply holes 21 flows downward through the reactive gas supply holes 21 and is supplied to the processing space 10. On the other hand, in the reactive gas supply hole 21 whose channel length is longer than that of the gas inlet hole 231, the radicals in the reactive gas that contribute to the film formation may be deactivated by the contact with the sidewall surface 211.

Therefore, as shown in FIG. 3, in the shower plate 2 of this example, a cover gas is supplied from the cover gas supply hole 221 to cover the sidewall surface 211 when viewed from the flow of the reactive gas. Due to the flow of the cover gas, the increase in the concentration of radicals in the area near the sidewall surface 211 is suppressed, so that the deactivation of radicals due to the contact with the sidewall surface 211 can be suppressed. As a result, the reactive gas with high concentration of radicals is supplied to the processing space 10. When the pressure in the processing chamber 11 is within a range of 0.133 Pa to 1.33 kPa (1 torr to 10 torr) and the flow velocity of the supply gas containing the plasma-state reactive gas in the reactive gas supply holes 21 is within a range of 1 m/sec to 10 m/sec, it is preferable to adjust the flow velocity of the cover gas supplied from the cover gas supply holes 221 to be within a range of 1 m/sec to 50 m/sec.

In addition, the raw material gas injected from the raw material gas supply holes 24 is also supplied to the processing space 10.

In the case of performing film formation by a CVD method, the supply of the plasma-state reactive gas through the reactive gas supply holes 21 and the supply of the raw material gas through the raw material gas supply holes 24 may be performed at the same time.

In the case of performing film formation by an ALD method, for example, the cycle of “the supply of raw material gas through the raw material gas supply holes 24 (adsorption of precursor to the wafer W)→the supply of purge gas through the reactive gas supply holes 21 and the raw material gas supply holes 24→the supply of plasma-state reactive gas through the reactive gas supply holes 21 (reaction with the precursor adsorbed to the wafer W)→the supply of purge gas through the reactive gas supply holes 21 and the raw material gas supply holes 24” is repeated a predetermined number of times.

After the film formation using the CVD method or the ALD method is performed for a preset period, the supply of the reactive gas, the raw material gas and the cover gas, and the supply of the RF power to the electrode plate 61 are stopped. Thereafter, the wafer W on which the film is formed is unloaded from the processing chamber 11 in the reverse sequence of the loading operation.

### <Effects>

The film forming apparatus 1 according to the present embodiment has the following effects. A cover gas is supplied to cover the sidewall surfaces 211 of the reactive gas supply holes 21 through which the plasma-state reactive gas flows in the plasma generation space 6. As a result, the increase in the concentration of radicals on the surfaces of the sidewall surfaces 211 is suppressed, and the reactive gas can be supplied to the wafer W to perform film formation while suppressing the deactivation of the radicals.

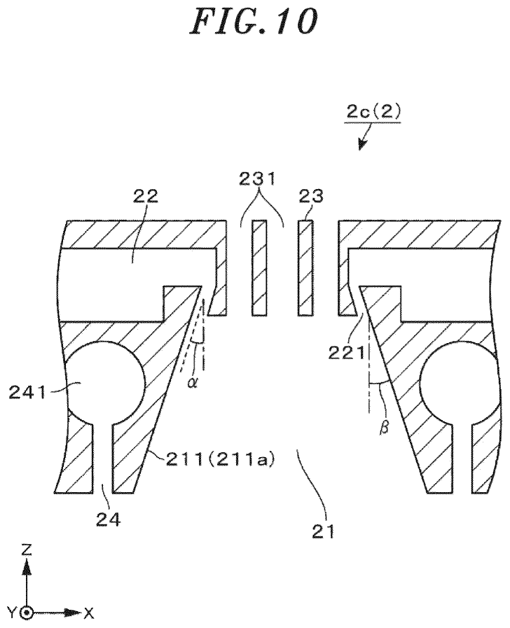

In the shower plate 2c according to the third embodiment shown in FIG. 10, the entire sidewall surface 211 is formed by the tapered surface 211a from the upstream end side to the downstream end side of the flow of the reactive gas in the reactive gas supply hole 21. The cross-sectional area of the reactive gas supply hole 21 increases in the flow direction of the reactive gas. Therefore, the sidewall surface 211 becomes gradually distant from the flow of the plasma-state reactive gas, so that the deactivation of the radicals can be more effectively reduced.

Here, when the angle between the discharge direction of the cover gas from the cover gas supply hole 221 and the vertical direction is set as a, and the angle between the tapered surface 211a of the sidewall surface 211 and the vertical direction is set as B, the relationship between the angles α and β may be “α>β” or “α≤β.”

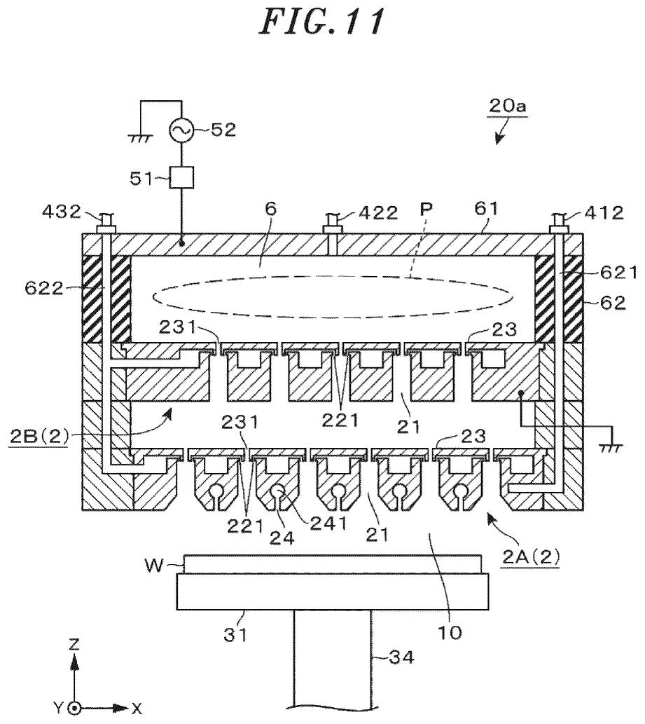

FIG. 11 shows a configuration of a gas shower head 20a having a plurality of shower plates, for example, two shower plates 2A and 2B, spaced apart from each other between the plasma generation space 6 and the processing space 10. In the shower plates 2A and 2B arranged adjacent to each other horizontally, the plurality of reactive gas supply holes 21 are formed at misaligned positions when viewed from the placing table 31 side (positions that do not overlap with each other when projected onto the plane parallel to the wafer W). With this configuration, the collision of the plasma-state reactive gas with the trap plate 23 on the upper surface of the shower plates 2A and 2B and the passage of the plasma-state reactive gas through the gas inlet holes 231 can be repeated multiple times. As a result, a larger amount of ions can be removed from the reactive gas. Meanwhile, in the reactive gas supply holes 21 of the respective shower plates 2A and 2B, the cover gas flows to cover the sidewall surfaces 211, so that the deactivation of radicals is suppressed.

Here, the plasma generation mechanism of the film forming apparatus 1 is not limited to a parallel plate type configuration, and may generate plasma by microwaves. Further, inductively coupled plasma (ICP), which is plasma of a processing gas obtained by generating eddy currents by high-frequency fluctuating magnetic field generated around an antenna, may be used.

In addition, it is not necessary to provide a trap plate 23 in the reactive gas supply hole 21, and the reactive gas supply holes 21 may be opened directly toward the plasma generation space 6. On the other hand, it is not necessary to provide an area where the tapered surface 211a is formed on the lower end side of the reactive gas supply hole 21. As can be seen from the shower plate 2B shown in FIG. 11, the reactive gas supply holes 21 may be configured such that the opening area does not change along the flow of the reactive gas. Further, it is not necessary to form the cover gas channel 22 in the shower plate 2. For example, a pipe for supplying a cover gas toward the sidewall surface 211 of each reactive gas supply hole 21 may be provided along the upper surface of the shower plate 21.

Further, the cover gas supply holes 221 are not necessarily provided on the upstream end side of the flow of plasma-state processing gas in the reactive gas supply holes 21. For example, in the elongated opening-shaped reactive gas supply holes 21a shown in FIG. 5, the cover gas supply holes 221 for supplying the cover gas laterally may be provided along the long side direction of the sidewall surfaces 211.

Further, the cover gas supply holes 221 do not necessarily provide the cover gas along the entire inner circumferential surfaces of the reactive gas supply holes 21. For example, in the elongated opening-shaped reactive gas supply holes 21a shown in FIG. 5, the cover gas supply holes 221 are provided on the sidewall surfaces 211 on the long side, whereas the cover gas supply holes 221 are not provided on the sidewall surfaces 211 on the short side. In addition, the cover gas is not limited to an inert gas, and may be, e.g., a reactive gas (processing gas) that is not converted into plasma.

Further, the above-described gas shower heads 20 and 20a are not necessarily applied to the film forming apparatus 1 for forming a film on the wafer W by causing the raw material gas to react with the plasma-state reactive gas. For example, they may be applied to a film forming apparatus for forming a film by supplying the plasma-state raw material gas (processing gas) to the surface of the wafer W. In this case, the raw material gas is supplied to the plasma generation space 6, and the plasma-state raw material gas is supplied to the processing space 10 through the reactive gas supply holes (the processing gas supply hole) 21 to which the cover gas is supplied. In this case, the shower plate 2 is not provided with the raw material gas channel 241 or the raw material gas supply holes 24 that are separate from the reactive gas supply holes 21.

Further, the gas shower heads 20 and 20a configured as described above may be provided in the case of supplying various gases into the processing chamber 11 of the etching processing apparatus for etching a film on the wafer W by supplying a plasma-state etching gas to the wafer W, or a modifying apparatus for modifying a material on the wafer W using the plasma-state modification gas. In that case, the etching gas and the modifying gas correspond to the processing gas of the present disclosure.

It should be noted that the above-described embodiments are illustrative in all respects and are not restrictive. The above-described embodiments may be omitted, replaced, or changed in various forms without departing from the scope of the appended claims and the gist thereof.

### Test Example

The fluid simulation was performed to obtain the concentration distribution of radicals in the reactive gas supply holes 21 in the case of supplying the cover gas from the cover gas supply holes 221 to cover the sidewall surfaces 211 of the reactive gas supply holes 21 through which the plasma-state reactive gas flows.

### A. Simulation Conditions

Under a pressure condition of 1.33 kPa (10 torr), the reactive gas containing radicals with a mass fraction of 0.1 was supplied from the plasma generation space 6 side to the reactive gas supply holes 21 at a flow rate of 5 m/sec. The diameter of the reactive gas supply holes 21 was 10 mm, and the channel length thereof was 15 mm (flow rate 0.248 slm/min). The mass fraction distribution of radicals contained in the fluid in the reactive gas supply holes 21 was simulated under the condition that the cover gas with a radical mass fraction of 0 was supplied to the reactive gas supply holes 21 from the cover gas supply holes 221 with an opening width of 1 mm at a flow rate of 20 m/sec (flow rate 0.191 slm/min).

### B. Simulation Results

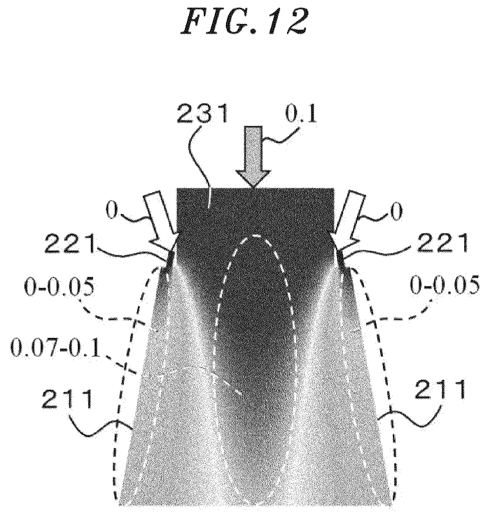

The simulation results are shown in FIG. 12. According to the results shown in FIG. 12, the mass fraction of radicals in the central region of the reactive gas supply holes 21 was within a range of about 0.07 to 0.1, and the mass fraction distribution of radicals was maintained similarly to that in the case of supplying the reactive gas to the reactive gas supply holes 21. On the other hand, the mass fraction distribution of radicals near the sidewall surfaces 211 covered by the flow of the cover gas was suppressed to a low concentration range of about 0 to 0.05. Therefore, it is clear that the supply of cover gas that flows to cover the sidewall surfaces 211 contributes to the reduction of the radical concentration near the sidewall surfaces 211 and thus can effectively suppress the deactivation of radicals due to the contact with the sidewall surfaces 211.

1. An apparatus for performing plasma processing by supplying a plasma-state processing gas to a substrate in a processing chamber, comprising:
a placing table disposed in the processing chamber and on which the substrate is placed;
a plasma generation space disposed above the placing table and constituting a plasma generation mechanism configured to convert the processing gas into plasma;
a processing gas supply part configured to supply the processing gas to the plasma generation space;
a shower plate disposed between the plasma generation space and a substrate processing space where the placing table is disposed, and having a plurality of processing gas supply holes through which the plasma-state processing gas flows from the plasma generation space toward the processing space, and
a cover gas supply mechanism configured to supply a cover gas that flows to cover sidewall surfaces of the plurality of processing gas supply holes.

2. The apparatus of claim 1, wherein the cover gas supply mechanism includes a cover gas channel formed in the shower plate and having a cover gas supply hole for supplying the cover gas on the sidewall surfaces of the processing gas supply holes, and a cover gas supply part configured to supply the cover gas to the cover gas channel.

3. The apparatus of claim 2, wherein the cover gas supply hole is opened at a position where the cover gas is supplied from an upstream end side of the flow of the plasma-state processing gas in the processing gas supply holes.

4. The apparatus of claim 2, wherein the cover gas supply hole is opened at a position where the cover gas is supplied along the entire inner circumferential surfaces of the sidewall surfaces of the processing gas supply holes.

5. The apparatus of claim 1, wherein the processing gas supply hole is provided with a trap plate that covers an opening on the plasma generation space side and collides with the plasma-state processing gas, and the trap plate has one or multiple gas inlet holes whose total opening area is smaller than an opening area of the processing gas supply holes.

6. The apparatus of claim 1, wherein the sidewall surfaces of the processing gas supply holes include an area defined by a tapered surface whose opening area gradually increases from an upstream side toward a downstream side of the flow of the plasma-state processing gas.

7. The apparatus of claim 1, wherein the plurality of processing gas supply holes are arranged such that a plurality of elongated openings are arranged side by side toward the processing space when viewed from the placing table side.

8. The apparatus of claim 1, wherein the processing gas supply holes are formed such that a plurality of small holes are arranged in a matrix shape when viewed from the placing table side.

9. The apparatus of claim 1, wherein the plasma generation space is formed between the shower plate made of a metal and an electrode plate spaced apart from the shower plate by a gap with a dielectric interposed therebetween, and
the plasma formation mechanism includes a radio frequency (RF) power supply connected to one of the electrode plate and the shower plate, and a ground terminal connected to the other one, and the processing gas supplied to the plasma generation space is converted into plasma by capacitive coupling between the electrode plate and the shower plate.

10. The apparatus of claim 1, wherein the shower plate has, in addition to the plurality of processing gas supply holes, a plurality of raw material gas supply holes for supplying a raw material gas that reacts with the plasma-state processing gas to form a film on the substrate toward the processing space, and the cover gas supply mechanism does not supply the cover gas to the raw material gas supply holes.

11. The apparatus of claim 1, wherein a plurality of the shower plates spaced apart from each other are provided between the plasma generation space and the processing space.

12. The apparatus of claim 11, wherein in the plurality of shower plates adjacent to each other, the plurality of processing gas supply holes are formed at misaligned positions when viewed from the placing table side.

13. The apparatus of claim 1, wherein the cover gas is an inert gas.

14. The apparatus of claim 1, wherein the processing gas is a processing gas that has not been converted into plasma.

15. A method for performing plasma processing by supplying a plasma-state processing gas to a substrate in a processing chamber,
wherein a placing table disposed in the processing chamber and on which the substrate is placed, a plasma generation space disposed above the placing table and constituting a plasma generation mechanism configured to convert the processing gas into plasma, and a shower plate disposed between the plasma generation space and the substrate processing space and having a plurality of processing gas supply holes through which the plasma-state processing gas flows from the plasma generation space toward the processing space are used,
the method comprising:
supplying the processing gas into the plasma generation space;
converting the processing gas supplied to the plasma generation space into plasma by the plasma formation mechanism;
supplying the plasma-state processing gas from the plasma generation space to the substrate on the placing table in the processing space through the plurality of processing gas supply holes of the shower plate; and
causing a cover gas to flow to cover the sidewall surfaces of the plurality of processing gas supply holes in said supplying the processing gas.
